(19) United States
(12) Patent Application Publication
(10) Pub. No.: US 2026/0223612 A1
(43) Pub. Date: Jul. 30, 2026

(54) LASER-ASSISTED MULTI-LEVEL MICROCHANNEL FABRICATION METHOD

(71) Applicant: IHSAN DOGRAMACI BILKENT ÜNIVERSITESI, Çankaya, Ankara (TR)

(72) Inventors: Onur TOKEL, Çankaya, Ankara (TR); Muhammad Ahsan TAUSEEF, Çankaya, Ankara (TR); Rana Asgari SABET, Çankaya, Ankara (TR)

(21) Appl. No.: 19/150,629

(22) PCT Filed: Feb. 7, 2024
(86) PCT No.: PCT/TR2024/050098

§ 371 Date: Jul. 24, 2025

(30) Foreign Application Priority Data
Mar. 23, 2023 (TR) 2023/003165

(51) Int. Cl. H10P 34/42; H10P 50/64

(52) U.S. Cl. CPC H10P 34/42; H10P 50/642

(57) ABSTRACT

The invention is a fabrication method for multi-level, high-quality and high-aspect ratio, fully buried microchannels with various geometries and architectures inside the bulk of silicon (Si).

### TECHNICAL FIELD

The invention is a fabrication method for multi-level, high-quality and high-aspect ratio, fully buried microchannels with various geometries and architectures inside the bulk of silicon (Si) substrate.

### STATE OF THE ART

Semiconductors establish the fundamentals of modern technology, in particular with electronics and computing. Unlike most other materials, Si has the unique advantage of being complementary metal oxide semiconductor (CMOS) compatible. For the entire semiconductor industry so far, the applications are residing on the top of the wafer. While proof-of-concept optical elements within Si is shown, to date, the capability of fabricating fully buried multi-level channels with diversity in the length, depth, geometry, and architecture has not been shown. If possible, to create such buried microchannels could be used to address one of the most critical limitations of current computers, i.e., the notorious heat-wall problem. Currently, further increasing the clock speed to improve computer performance is not possible, because hot spots on the chip surface would not be cooled effectively. If microchannels buried right below the surface can be fabricated, by running cooling water inside the chip, local removal of heat could be engineered, leading to significant performance boosts. Hence, microchannels created inside Si with unaltered chip surface would be a very powerful platform for integrating “on-chip” systems to “in-chip” devices for strongly improved device performance.

EP1427010A1 discloses a method of first creating the surface channels, then partially closing these with epitaxial growth process. This corresponds to a method to fabricate silicon-on-insulator (SOI) wafer creating channels very close to the wafer surface, (i.e., right under the 1-10 μm epitaxial layer up to ~10 μm depth). Using the method in EP1427010A1, one has limited control in channel geometry, which are not completely inside the crystal silicon bulk.

Similarly, CN110379780A discloses microchannels, fabricated on the surface of silicon and then covered with film.

U.S. Pat. No. 7,471,866B2 discloses a method for controlled fabrication of planar waveguiding structures with embedded microchannels having substantially circular or elliptical cross-sections in silicon-based glass materials based on masks.

As such, conventional lithography techniques and laser ablation methods are used for creating surface channels on Si. However, there is no technology available to create non-straight or multi-level channels buried inside Si. Some limited version of straight subsurface channels may (in principle) be created with Reactive Ion Etching, however with very high cost and effort, and this would be extremely impractical. An exciting direction for fabrication inside transparent materials is to exploit the direct laser writing techniques accompanied with chemical etching. While similar laser-assisted chemical etching methods have been shown to create channels in glasses, highly controlled microchannel fabrication in Si remains impossible.

In state of the art, fabrication of through-Si-vias by first polishing the sample for access to the modified areas and treating it with the developed chemical etchant was reported (Deminskyi, Petro, et al. APS March Meeting Abstracts. Vol. 2018, 2018, Tokel et al, Nature Photonics 11, 639, 2017). These initial efforts were limited to the wafer surface or required numerous post processing steps. In addition, fabrication limitations on channel architecture, multi-level writing, fabrication of curved in-chip microchannels, high-throughput fabrication capability, and critically, the protection of wafer surface for future CMOS integration, have not been shown before. Developing these methods lead us to introduce a comprehensive in-chip microchannel fabrication technique including all claims of this invention, while introducing multi-level and non-straight channel fabrication.

### FIGURES

FIG. 1: A schematic block diagram of method of invention

FIG. 2: Schematic representing two laser-writing modalities: (a) Transverse writing modality, where laser scans perpendicular to the propagation direction, (b) Longitudinal writing modality, where the laser propagation is parallel to sample scanning direction.

FIG. 3: (a) Effective etching rate measured as a function of pulse energy. For subsurface interplanar separation of Λ=11 μm and number of planes=16, the cut-off for pulse energy is observed at 4.3 μJ. Up to this point, there is a reproducible, high quality channel fabrication. (b) Effective etching rate as given a function of number of subsurface planes. The cut-off for number of planes is found as 20, for Λ=11 μm and Eₚ=4.3 μJ. The highest etching rate corresponding to the in-chip array is 750 μm/h.

FIG. 4: (a) Scanning Electron Microscope (SEM) image of a single channel cross section microchannel created buried inside Si. (b) SEM image (this time in x-z plane) showing depth control of microchannels inside Si. (c) SEM image of a 3×3 array multi-level array of microchannels fabricated inside Si.

FIG. 5: (a) SEM image of a curved channel revealed through CMP. (b) High-definition camera image of a set of 4 curved microchannels. The inset is a zoomed-in version of a single curved channel. (c) IR transmission microscopy image of an end-to-end opened in-volume curved microchannel inside Si.

FIG. 6: (a) SEM images of high-aspect-ratio (25) channels, with diverse port geometries, (i) circular, (ii) square, (iii) triangular shapes. These are fabricated with a highly localized spatially modulated beam Bessel beam. (b) SEM image of a square cross-sectional through-silicon via (TSV).

FIG. 7: (a) Optical profilometer device (OPD) image of the wafer surface after channel fabrication. The average roughness (Ra) is measured as 2.2 nm. (b) OPD image of a control sample, pristine Si surface, has surface roughness of 2.0 nm. (c) SEM image of the Si surface after channel fabrication, showing no morphological change.

### BRIEF DESCRIPTION OF THE INVENTION

For over 50 years, computers became faster mainly thanks to better packaging and increasing clock rates. However, Moore's law is now faltering and there is an urgent need for new solutions to overcome the heat removal and related clock speed challenges. Chip makers responded by switching to multi-core architectures, but the stubborn heat accumulation problem was back shortly. This is especially true for GPUs, which represent the cutting edge of computing in diverse areas from scientific computing to autonomous cars. A modern GPU dissipates 500 Watts of heat, which limits its denser integration, thus, ultimately its performance. A potential solution is to create meandering subsurface microchannels for delivering cooling fluids to hotspots. However, this requires truly 3D architectures, involving, e.g., a network of truly buried (in-chip) microfluidic channels for efficient heat dissipation, similar to cooling by blood vessels in the human brain. In this invention, laser-writing of in-chip multi-level, multi-architecture microchannels with strong control is shown, as a precursor for this holy grail.

In prior art, there is no technology available to create non-straight channels inside Si. Some limited version of straight subsurface channels may (in principle) be created with Reactive Ion Etching, however with very high cost and effort, but this would be extremely impractical.

Prior art does not disclose a method for fabricating curved or multi-level buried microchannels inside bulk silicon. Also controlling the horizontal channel entrance port geometry e.g., triangular or square shape, is not possible by methods disclosed in prior art.

Some objects of the invention are,
Fabricating high-quality, multi-level, high-aspect-ratio (up to 25) microchannels buried inside silicon wafer. The longest buried micro-channel has a length of 5 mm.
Creating diverse architectures with different laser-writing modalities. This includes multi-level and curved channel fabrication, as well as top-to-bottom (thru-Si-vias) or horizontal channels.
Controlling the channel cross-section geometry. This includes circular, triangular or rectangular shaped ports.
Preserving device-level wafer surface quality which is achieved with passivation, for future on-chip device integration. The surface has a roughness of 2.2 nm, similar to pristine Si surface.
Achieving state-of-the-art, highest effective etching rate for buried channels, i.e., 750 μm/h.

### DETAILED DESCRIPTION OF THE INVENTION

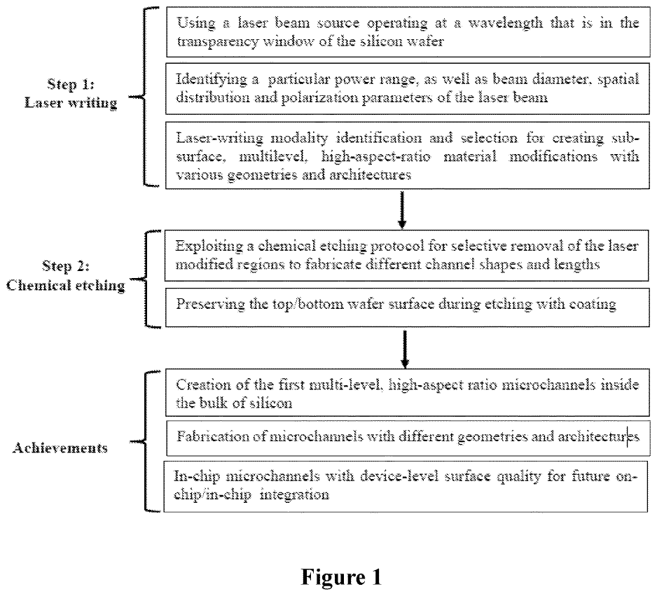

The invention is a fabrication method to create fully buried microchannels in the bulk of silicon while preserving the device-level quality of top wafer surface. For this purpose, the invention will leverage state-of-the-art laser-sculpting technique that resulted in the formation of surface microchannels. By overcoming current limitations, the invention provide fabrication of sub-surface microchannels inside silicon. Further, through-silicon vias (TSVs) are fabricated by the invention, from the top to the bottom surface of wafer, without requiring any additional steps, such as polishing. A schematic block diagram of method of invention is shown in FIG. 1.

The technique of the invention enables the fabrication of in-chip (or in-volume) multi-level microchannels without damaging the top surface of Si. It employs a two-step method with various laser-writing modalities and specific laser and focusing parameters, as well as novel writing based on creating arrays. Step one entails nonlinear writing to induce permanent modifications and creating arrays in Si. Second step involves selective etching of laser-written arrays to reveal channel arrays.

### Two-Step Fabrication Approach for Subsurface Microchannels

Step one entails non-linear laser writing process to induce subsurface permanent modifications deep inside silicon. This is followed by the second step, which involves selective etching of the laser-written structures with a chemical etchant. This approach enables us to demonstrate the first sub-surface microchannels with complete wafer surface protection, simultaneously, with capability of controlling channel depth measured from the wafer surface, channel cross-sectional geometry and aspect ratio. In addition, the quality of inner channel walls will be high.

In a preferred embodiment, example application of Step 1 is given below.

### Step 1: Laser Writing Inside Silicon

The light source in the setup of the invention is a master oscillator power amplifier system (MOPA) that operates in the transparency window of Si. It is a custom-built nanosecond laser operating at a wavelength at 1550 nm, a repetition rate of 150 kHz, and a pulse duration of 10 ns. The laser is capable of producing a maximum output of 6 W. The beam output has a profile of a gaussian beam. The output from the laser is passed through a quarter-wave plate (QWP) and half-wave plate (HWP) to control its power. This is followed by a polarized beam splitter to transmit linearly-polarized light. In the process of invention, a spatial light modulator (SLM) to control and modulate the shape or phase profile of the beam is used. Before the beam is projected onto the SLM, it is passed through a pair of lenses, serving as a telescope, to collimate and expand the beam. The lenses L1 and L2 have focal lengths of f1=15 mm and f2=35 mm. The beam is then projected and reflected through the liquid crystal on the silicon SLM with 792×600 pixels and 20 μm pixel size. The SLM modulates the phase profile of the beam. A Gaussian beam for laser writing is preferred. Therefore, SLM works as a mirror mainly, however we will show some early results from the use of SLM in the later parts, in particular for controlling the channel aspect ratio.

Before the beam is passed through the last focusing lens, its diameter needs to be adjusted according to the aperture of the aspheric focusing lens. Therefore, a 4f system is used to de-magnify the beam (f3=125 mm, f4=100 mm). The focusing aspheric lens (AFL) has a focal length of 4.5 mm. The AFL directly focuses the beam into the bulk of the Si sample, where it induces non-linear interactions at the focal point, resulting in localized material change. The beam width at the focal point is 3 μm at 1/e2 of maximum. In order to scan the sample with respect to the laser, it is mounted on a 3D positioning stage, with a resolution on the order of nanometers. The stage is controlled with a computer code, which is capable of creating almost any complex 3D shape, and consequently laser-written structures in Si.

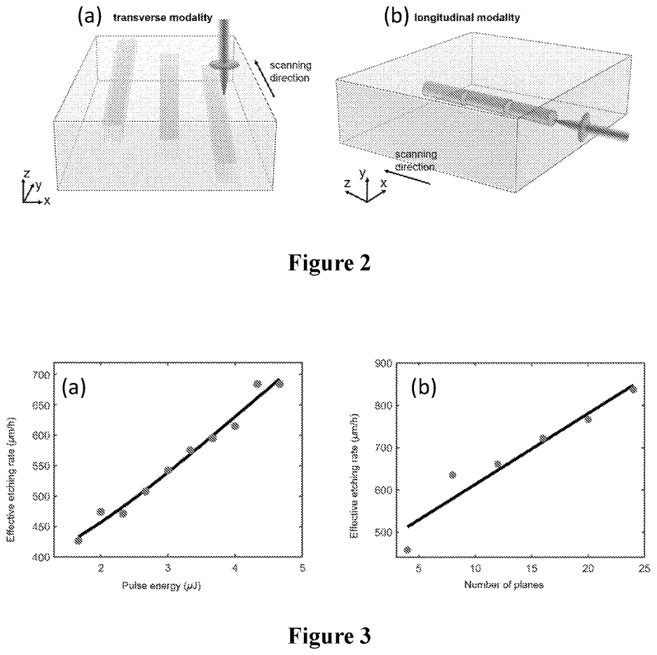

Laser writing modalities: Transverse and longitudinal laser-writing modalities are used interchangeably, due to corresponding benefits. The transverse and longitudinal modalities refer to scanning the sample perpendicular and parallel to laser propagation direction, respectively (FIG. 2). While the transverse mode allows writing in arbitrary lengths simply by scanning, the longitudinal modality allows better control on cross-sectional geometry and dimension. In longitudinal writing, the length of modification may seem limited by the region where the laser is focused. However, it is possible to coherently stitch modifications along the optical axis to increase the length (5 mm length is shown, but we expect this to increase with further optimization of laser parameters).

In a preferred embodiment example application of Step 2 is given below.

### Step 2: Selective Etching of Laser Modified Regions Inside Si

Once laser-written modifications in Si are created with desired geometry, the next step is to selectively remove them, in order to create a fully-buried microchannel or a TSV. As mentioned in the light-material interaction section, areas exposed to multiphoton absorption experience a crystal disruption. Hence, a preferred etchant would be the one that selectively attacks only disrupted regions and leave the crystalline silicon unaffected. It includes a combination of chemicals that simultaneously work together in order to perform the desired etching task.

The etchant is comprised of a mixture of chemicals with the corresponding compositions given in the following sequence: copper II nitrate (Cu(NO₃)₂): 0.05 M (3 gr.), hydrofluoric acid (HF): 10 M (36 ml.), nitric acid (HNO₃): 4 M (25 ml.), and acetic acid (CH₃COOH): 3.5 M (24 ml.). The process of etching involves oxidizing and subsequently dissolving the laser-irradiated regions. Each chemical performs a certain function. For instance, HNO₃ is used as an oxidizing agent, HF removes the oxidized areas, Cu(NO₃)₂ reduces the activation energy of the process, thereby increasing the selectivity, and CH₃COOH is used as a diluting agent. The mixture is carefully prepared in the cleanroom on a wet bench, designated for this purpose. While preparing the etchant, all safety precautions are taken with respect to the material safety data sheet (MSDS) of each chemical used in the process.

The beam is then transmitted or reflected through a physical or digital element for spatial beam modulation. A Gaussian beam or axicon type modulation is used, producing the zeroth-order of the first kind Bessel function. The latter is created with liquid-crystal-on-silicon spatial light modulator (LCOS-SLM). In the case of zero-order Bessel beam, conical phases with different signs and angles (O) can be applied to the SLM. A 4-f optical arrangement relays the beam onto the last focusing lens. With this system, the conical angle can be magnified, or the Gaussian beam diameter on the focusing lens aperture can be adjusted. An aspheric lens of a 4.5 mm focal length for focusing in Si is preferred, but other high numerical aperture (NA) lenses (>0.4) can also be used. The focused beam inside Si sample induces a highly non-linear effect resulting in localized material change. To scan the sample with respect to the laser, a precise computer-controlled 3D positioning stage is used. The laser system and the stage can create almost any complex 3D shape, consequently diverse laser-written structures embedded in Si.

An important advance is the realization that in order to fabricate microchannels with controlled quality and dimensions, a specific arrangement of individual micro-modifications (Λ) is required, as well as the number of individual modification planes. One also needs to ensure that modification arrays do not result in uneven formations and/or cracking inside the chip due to excess stress/strain accumulation. These are collectively solved by creating a laser-written microchannel from an array of thin multi-level planes.

Two different types of samples as preferred silicon wafers with difference in their crystallographic orientation and resistivity are used. A 1-mm thick p-doped <100> type silicon sample with a resistivity of 1-10 Ω·cm and a 1-mm thick p-doped <111> type Si sample with a resistivity of 1-10 Ω·cm. For Gaussian beam and transverse writing modality experiments, p-doped <111> samples were preferred. Similarly for longitudinal modality and Bessel written structures, p-type <100>, side-polished samples were preferred. No discernible difference in the channels between samples is observed. Similarly, the thickness of the sample is not strictly limited to 1 mm for the technique of the invention.

### Dicing

The subsurface laser modifications are fully buried in three-dimensions. It is a simple yet crucial step to expose the modifications from the sides to make way for the etchant. For this purpose, DISCO DAD3220 dicing machine is used to dice the wafer and reveal the two end ports of the microchannel template, before Si is dipped into the chemical etchant. In another embodiment of the method, laser-written volume extends all the way to wafer side surfaces. In this case, dicing is not required, and one can create the channels through passivation and etching.

After dicing, samples are carefully cleaned to remove any organic or inorganic impurities that may have been deposited over the sample. Acetone, Isopropanol, and de-ionized water in sequence is used, where the sample is washed in an ultrasonic bath for a total of 15 minutes. The sample is then dried with nitrogen gas. This cleaning procedure is used before the laser-writing and chemical etching steps.

### Photo-Resist Passivation

In order to avoid any damage to the sample surface, a systematic study of different photoresist (PR) coating was conducted. In a preferred embodiment, a pipette was used to coat the photoresist, to allow a thick protective layer to be deposited. Then PR was hard baked at 120° C. for 5 minutes. The PR was successful in preserving the sample surface for at least 75 minutes. In order to fabricate microchannels that require longer etching periods, a time-multiplexed alternative process of coating and etching was employed. The sample was etched with photoresist for 75 mins, after which it removed from the etchant and then coated again before dipping it into the etchant again. These steps are followed recursively for protection of samples which require longer etching time. Two examples for preferred photoresist are AZ-5214E and AZ-4562 as brand names, with different hard-baking times.

In order to validate the method, advanced 2D/3D imaging methods were used for surface and sub-surface characterization. To image the laser-written structures in-situ, infrared transmission microscopy is used. For surface analysis, such as cross-sectional imaging of an opened microchannel, scanning electron microscopy (SEM) is used. In order to characterize wafer surface quality after fabrication, optical profilometer device (OPD) and energy dispersive x-ray spectroscopy (EDXS) is used. Significant structural limitations and instabilities are overcome by identifying a suitable regime for the spacing between individual subsurface planes (Λ), laser pulse energy (Eₚ), and the number of subsurface planes. The highest etching rate for a given architecture is found with a systematic study on the laser pulse energy and channel cross-section (FIG. 3a). A linear dependency in the effective etching rate (defined as the total etched length of the channel per minute) with respect to laser pulse energy shows that, for a microchannel of Λ=11 μm and number of planes=16, the highest etching rate is achieved with Eₚ=4.3 μJ, We note that if one increases the pulse energy further, induced stress-accumulation causes structural instability and cracks, resulting in a cut-off value for laser pulse energy. Experiments indicate that exact cut-off value depends on the architectural details of building blocks of individual channels, in this case, the separation (A) between subsurface planar modifications.

A second architectural aspect, cross-sectional area is found to effect the effective etching rate. This is because larger areas provide higher surface area for the chemical etchant to open the channel. This creates a cut-off value in the number of planes per channel, due to induced stress, as identified below. For instance, a microchannel of Λ=11 μm, Eₚ=4.3 μJ, is found to have a cut-off value for the number of subsurface planes as 20. For these parameters the effective etching rate is found as high as 750 μm/h (FIG. 3b). This value is the highest channel etching rate inside Si, which is higher even compared to analogous experiments in glasses (363 μm/h, C. A. Ross, et al. Optics Express, vol. 26, no. 19, pp. 24343-24356, 2018).

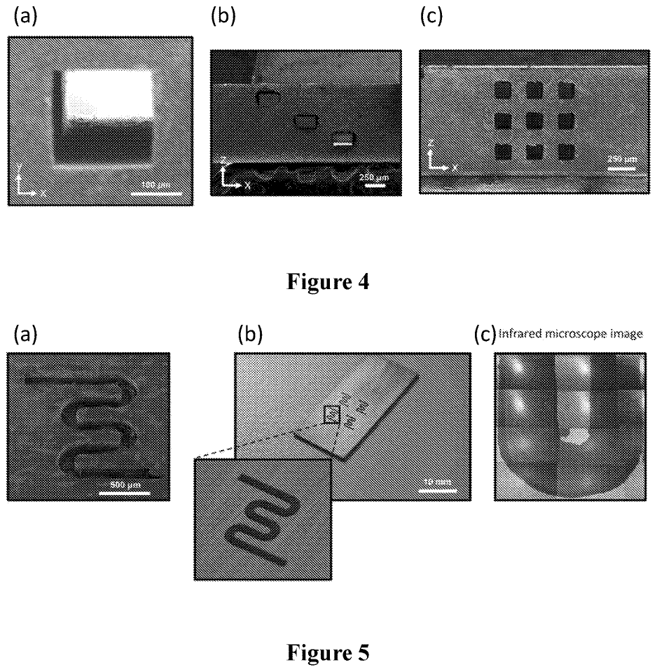

As a result of the procedure, very high-quality buried micro-channels (FIG. 4a) which can be positioned anywhere inside a wafer are obtained. For instance, three microchannels created at various depths are shown in FIG. 4b. In addition, multi-level arrays of microchannels (FIG. 4c) are obtained. These arrays are written level by level, starting from the bottom to the top level, and are etched all together. The laser parameters for each microchannel are: Eₚ=2.9 μJ, Λ=10 μm, and number of planes=14.

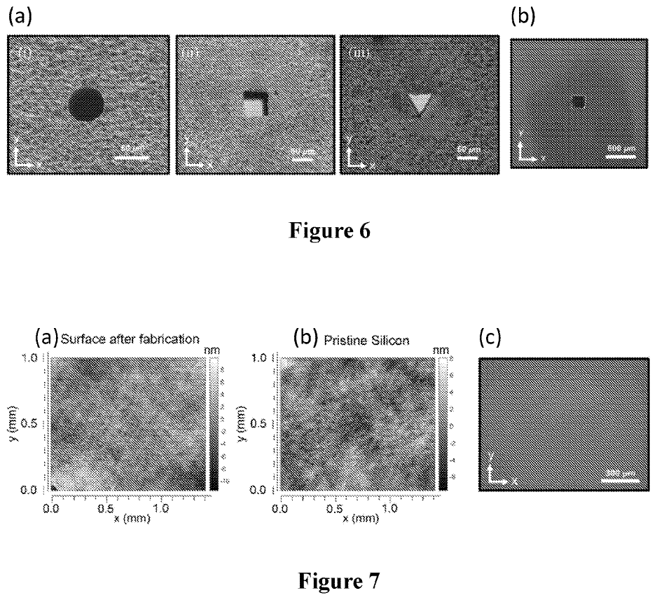

Another claim is creating a curved (FIG. 5) channel in the bulk of Si. For imaging these a unique approach was employed. The structures were first revealed at the surface using chemical mechanical polishing (CMP) and then etching for proof-of-concept (FIGS. 5a-5b). In parallel, in-situ imaging based on infrared transmission microscopy shows the buried channels (FIG. 5c). These constitute the first completely buried, end-to-end opened, curved microchannels. With this method, virtually any shape or networks of channels can be formed, depending on the requirements of the application. Another claim is cross-sectional geometry control. Bessel beams and longitudinal writing are used to create elongated (in the optical axis) modified lines. These are then arrayed closely in multiple axis, in order to form diverse shapes (FIG. 6). Thus, long channels were fabricated with different cross-sections, with an aspect ratio of 25 (FIG. 6a (i-iii)). Further, the method enables the creation of high-quality vertical channels (through-silicon vias), without requiring any pre-polishing steps (FIG. 6b).

Another claim is that the top/bottom wafer surface remains preserved after laser writing and etching. This would be critical for future applications, for instance potential in-chip integration with electronics. The average surface roughness of Si after fabrication was measured as 2.2 nm, using an OPD (FIG. 7). This value is comparable to pristine silicon (2.0 nm). This is achieved by coating the surface with a thin layer of AZ-5214E photoresist using a pipette. The sample was baked for 5 mins at 120° C. and left to rest for two hours before etching protocol. Energy dispersive x-ray spectroscopy (EDXS) analysis is used to confirm that no chemical impurities were left on the surface. Thus, the method protects the wafer surface from any potential alteration fabrication. Within these basic concepts, it is possible to develop various embodiments of novel “Laser-assisted multi-level microchannel fabrication method buried inside silicon” technique; and the invention is not limited to examples disclosed herein.

1. Method for fabricating a fully buried microchannel inside a silicon wafer comprising steps of:
i. operating a laser beam source at a wavelength that is in the transparency window of silicon wafer;
ii. laser-writing modality identification and selection;
iii. protecting upper and/or lower surfaces of silicon wafer from chemical etching by photo resist passivation; and
iv. chemical etching for selective removal of laser modified regions.

2. Method according to claim 1 wherein the laser beam source is pulsed laser operating at the transparency window of silicon, where λ is 1550 nm, repetition rate is 150 kHz, and pulse duration is 10 ns.

3. Method according to claim 2, wherein power control of the laser beam source is achieved either by couple of wave plates or neutral density filter.

4. Method according to claim 1, wherein before the laser-writing modality identification and selection, beam is transmitted or reflected through an element for spatial beam modulation.

5. Method according to claim 4, wherein the beam modulation is Gaussian or Bessel type modulation.

6. Method according to claim 1, wherein the laser-writing modality is transverse to scan the wafer perpendicular to laser propagation direction.

7. Method according to claim 1, wherein the laser-writing modality is longitudinal to scan the wafer parallel to laser propagation direction.

8. Method according to claim 1, wherein for said photo resist passivation, photoresist material is applied to upper and/or lower surface of silicon wafer, to form a protective layer and baked.

9. Method according to claim 1, wherein chemical etchant is formed by using at least one oxidizing agent, at least an activation energy reducing agent, at least one acid, at least one diluting agent.

10. Method according to claim 9, wherein the oxidizing agent is nitric acid.

11. Method according to claim 9, wherein the activation energy reducing agent is copper II nitrate.

12. Method according to claim 9, wherein the acid is hydrofluoric acid.

13. Method according to claim 9, wherein the diluting agent is acetic acid.

14. Silicon wafer with fully buried microchannel architectures produced according to the method of claim 1.

15. Silicon wafer according to claim 14, wherein the fully buried microchannel is located parallel to the top wafer surface.

16. Silicon wafer according to claim 14, wherein the fully buried microchannel is located perpendicular to the top wafer surface.

17. Silicon wafer according to claim 14, wherein the microchannel is multi-level.

18. Silicon wafer according to claim 14, wherein the microchannel is curved.

19. Silicon wafer according to claim 14, wherein the wafer surfaces are left as pristine Silicon for further on-chip device integration.
